(19) United States
(12) Patent Application Publication
(10) Pub. No.: US 2017/0214401 A1
(43) Pub. Date: Jul. 27, 2017

(54) SWITCH INCLUDING SENSOR FOR DETECTING TARGET TO BE DETECTED IN NON-CONTACT MANNER

(71) Applicant: Panasonic Intellectual Property Management Co., Ltd., Osaka (JP)

(72) Inventors: KOUHEI KORESAWA, Kyoto (JP); GOSUKE SAKAMOTO, Kyoto (JP)

(21) Appl. No.: 15/407,687

(22) Filed: Jan. 17, 2017

(30) Foreign Application Priority Data
Jan. 27, 2016 (JP) 2016-013875

(51) Int. Cl. H03K 17/955; G01V 3/08; H03K 17/78; G01S 17/02

(52) U.S. Cl. CPC H03K 17/955; G01S 17/026; G01V 3/088; H03K 17/78; G06F 3/011

(57) ABSTRACT

A switch includes a sensor that, in operation, outputs a detection signal indicative of approach of a target without making contact with the target, and a control circuit that, in operation, generates an operation signal for operating the apparatus on the basis of the detection signal supplied from the sensor. The control circuit generates the operation signal when the detection signal becomes smaller than a second threshold value within a predetermined period from a time when the detection signal exceeds a first threshold value that is different from the second threshold value and does not generate the operation signal when the detection signal becomes smaller than the second threshold value after elapse of the predetermined period from the time when the detection signal exceeds the first threshold value.

### BACKGROUND

1. Technical Field

The present disclosure relates to a switch.

2. Description of the Related Art

Conventionally, an operating switch is used for a user's operation such as an operation of turning an apparatus on or off. As a device including this kind of operating switch, Japanese Unexamined Patent Application Publication No. 2010-54765 discloses a video display device that is forcibly shut down by determining that the video display device can be shut down without any problem in a case where pressing of an electrostatic touch switch that is not intended by a user continues and where no video signal is being input, thereby preventing erroneous operation.

### SUMMARY

In one general aspect, the techniques disclosed here feature a switch for operating an apparatus, including: a sensor that, in operation, outputs a detection signal indicative of approach of a target without making contact with the target; and a control circuit that, in operation, generates an operation signal for operating the apparatus on the basis of the detection signal supplied from the sensor. The control circuit generates the operation signal when the detection signal becomes smaller than a second threshold value within a predetermined period from a time when the detection signal exceeds a first threshold value that is different from the second threshold value. The control circuit does not generate the operation signal when the detection signal becomes smaller than the second threshold value after elapse of the predetermined period from the time when the detection signal exceeds the first threshold value.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a block diagram of a non-contact operating switch according to Embodiment 1;

FIG. 2A is a plan view of a sensor used in the non-contact operating switch according to Embodiment 1;

FIG. 2B is a cross-sectional view of a sensor used in the non-contact operating switch according to Embodiment 1 taken along line IIB-IIB of FIG. 2A;

FIG. 3 is a diagram illustrating an example of use of the non-contact operating switch according to Embodiment 1;

FIG. 4 is a diagram for explaining a method for controlling a non-contact operating switch according to a comparative example;

FIG. 5 is a diagram illustrating a state where a user's head is close to the non-contact operating switch;

FIG. 6 is a diagram for explaining a method for controlling the non-contact operating switch according to Embodiment 1;

FIG. 7 is a diagram for explaining a method for controlling a non-contact operating switch according to Embodiment 2;

FIG. 8 is a diagram for explaining a method for controlling a non-contact operating switch according to Embodiment 3; and

FIG. 9 is a flowchart illustrating an example of processing of a control unit of a non-contact operating switch according to one aspect of the present disclosure.

### DETAILED DESCRIPTION

The technique disclosed in Japanese Unexamined Patent Application Publication No. 2010-54765 is not effective in a case where a switch for operating an apparatus in a non-contact manner is used. That is, it is impossible to prevent the switch from reacting to an operation that is not intended by a user.

Meanwhile, a switch according to one aspect of the present disclosure makes it possible to prevent a switch for operating an apparatus in a non-contact manner from reacting to an operation that is not intended by a user.

The present disclosure includes at least switches described in the following items.

### Item 1

A switch according to Item 1 of the present disclosure is a switch for operating an apparatus, the switch including: a sensor that, in operation, outputs a detection signal indicative of approach of a target without making contact with the target; and a control circuit that, in operation, generates an operation signal for operating the apparatus on the basis of the detection signal supplied from the sensor. The control circuit generates the operation signal when the detection signal becomes smaller than a second threshold value within a predetermined period from a time when the detection signal exceeds a first threshold value that is different from the second threshold value. The control circuit does not generate the operation signal when the detection signal becomes smaller than the second threshold value after elapse of the predetermined period from the time when the detection signal exceeds the first threshold value.

In the switch according to Item 1, the control circuit may include a processing circuitry and a memory storing a program, and the program, when executed by the processing circuitry, may cause the control circuit to generate the operation signal when the detection signal becomes smaller than the second threshold value within the predetermined period from the time when the detection signal exceeds the first threshold value.

### Item 2

In the switch according to Item 1, the first threshold value may be larger than the second threshold value.

### Item 3

In the switch according to Item 1, the first threshold value may be smaller than the second threshold value.

### Item 4

In the switch according to any one of Items 1 through 3, the sensor may include an electrode that, in operation, detects a change of electrostatic capacitance that occurs between the target and the sensor.

### Item 5

In the switch according to any one of Items 1 through 3, the sensor may include a light receiver that, in operation, receives an infrared ray reflected or radiated by the target and outputs the detection signal upon receiving the infrared ray.

In the present disclosure, all or a part of any of circuit, unit, device, part or portion, or any of functional blocks in the block diagrams may be implemented as one or more electronic circuits including, but not limited to, a semiconductor device, a semiconductor integrated circuit (IC) or a large scale integration (LSI). The LSI or IC can be integrated into one chip, or also can be a combination of plural chips. For example, functional blocks other than a memory may be integrated into one chip. The name used here is LSI or IC, but it may also be called system LSI, very large scale integration (VLSI), or ultra large scale integration (ULSI) depending on the degree of integration. A field programmable gate array (FPGA) that can be programmed after manufacturing an LSI or a reconfigurable logic device that allows reconfiguration of the connection or setup of circuit cells inside the LSI can be used for the same purpose.

Further, it is also possible that all or a part of the functions or operations of the circuit, unit, device, part or portion are implemented by executing software. In such a case, the software is recorded on one or more non-transitory recording media such as a ROM, an optical disk or a hard disk drive, and when the software is executed by a processor, the software causes the processor together with peripheral devices to execute the functions specified in the software. A system or apparatus may include such one or more non-transitory recording media on which the software is recorded and a processor together with necessary hardware devices such as an interface.

Embodiments of the present disclosure are described below. Note that each of the embodiments described below illustrates a specific example of the present disclosure. Numerical values, shapes, materials, constituent elements, ways in which the constituent elements are arranged and connected, and the like in the embodiments below are examples and do not limit the present disclosure. Various aspects described herein can be combined as long as no contradiction occurs. Among constituent elements in the embodiments described below, constituent elements that are not described in independent claims that indicate the highest concepts are described as optional constituent elements.

Each of the drawings is a schematic view and is not necessarily exact illustration. Therefore, scales and the like in the drawings do not necessarily match. In the drawings, elements that are substantially identical are given identical reference signs, and overlapping description is omitted or simplified.

### Embodiment 1

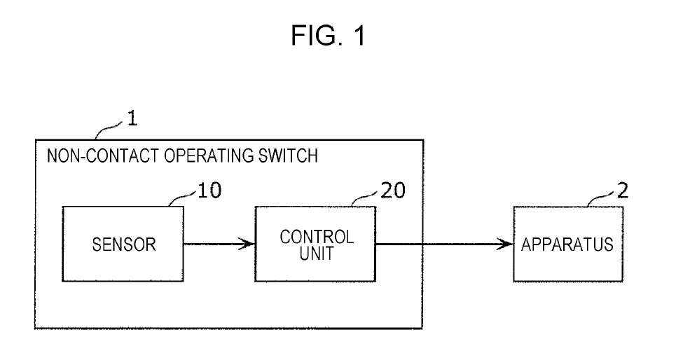

A configuration of a non-contact operating switch 1 according to Embodiment 1 is described below with reference to FIG. 1. FIG. 1 is a block diagram illustrating a configuration of the non-contact operating switch 1 according to Embodiment 1.

As illustrated in FIG. 1, the non-contact operating switch 1 includes a sensor 10 and a control unit 20 that generates an operation signal on the basis of a detection signal supplied from the sensor 10. The non-contact operating switch 1 controls an apparatus 2. For example, the non-contact operating switch 1 controls ON/OFF of the apparatus 2. The control unit 20 corresponds to a control circuit of the present disclosure.

The sensor 10 is a non-contact type sensor that is capable of detecting a target to be detected such as a human or an object in a non-contact manner. The sensor 10 is, for example, a capacitance type sensor that detects approach of a target to be detected by detecting a change of electrostatic capacitance that occurs between the target to be detected and the sensor 10. Note that the sensor 10 is capable of detecting a target to be detected not only in a case where the target to be detected approaches, but also in a case where the target to be detected makes contact with the sensor 10.

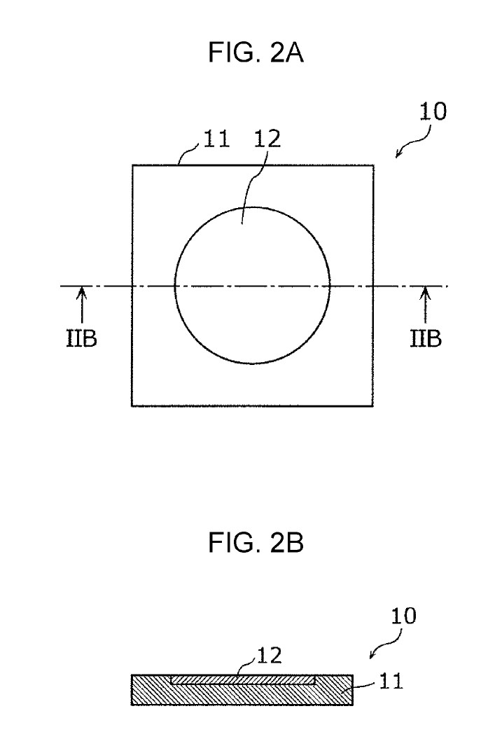

The capacitance type sensor 10 includes a substrate 11 and an electrode 12 disposed on the substrate 11, as illustrated in FIGS. 2A and 2B. FIG. 2A is a plan view of the sensor 10 used in the non-contact operating switch 1 according to Embodiment 1, and FIG. 2B is a cross-sectional view of the sensor 10 taken along line IIB-IIB of FIG. 2A.

The substrate 11 is, for example, a resin substrate made of a resin material, a metal-based substrate obtained by insulation-coating a metal, or the like. Note that the shape of the substrate 11 in plan view is, for example, rectangular but is not limited to this.

The electrode 12 is, for example, made of a metal material such as copper or silver and is provided on one surface of the substrate 11 in a predetermined pattern. Specifically, the electrode 12 has a circular shape in plan view and is disposed at the center of the substrate 11. Note that the shape of the electrode 12 in plan view is not limited to a circular shape and can be a rectangular shape or the like. The electrode 12 is electrically connected to an electric circuit (not illustrated) of the control unit 20 in order to detect a change of electrostatic capacitance caused by approach of a target to be detected.

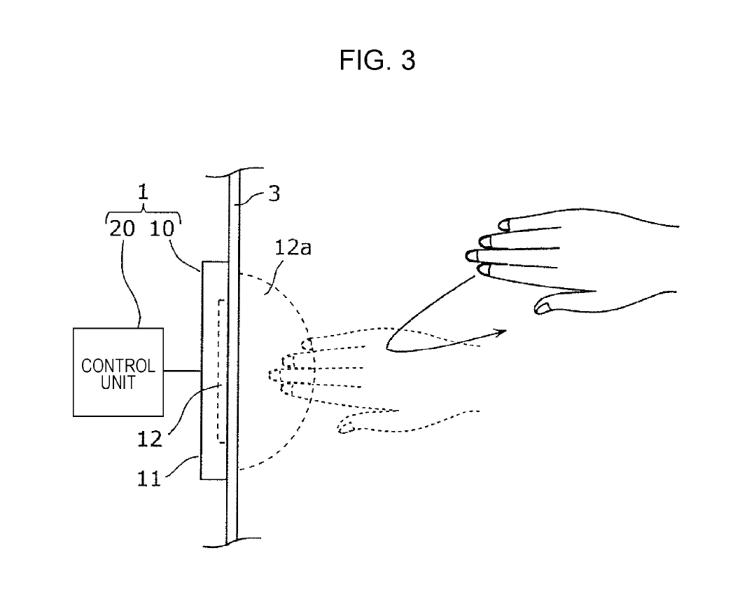

As illustrated in FIG. 3, the non-contact operating switch 1 is, for example, provided on a mirror 3 of a washing stand. FIG. 3 is a diagram illustrating an example of use of the non-contact operating switch 1 according to Embodiment 1.

Specifically, the sensor 10 is provided on a rear surface of the mirror 3. A detection region 12a is a region where a target to be detected can be detected by the electrode 12. That is, the electrode 12 functions as a sensor unit that detects approach of a target to be detected to the electrode 12 when the target to be detected enters the detection region 12a. With this arrangement, the sensor 10 detects a target to be detected and generates a detection signal when the target to be detected approaches.

As illustrated in FIG. 1, the control unit 20 receives a detection signal generated by the sensor 10, generates an operation signal for operating the apparatus 2, which is a target to be operated, on the basis of this detection signal, and then supplies the operation signal to the apparatus 2. This allows a user to perform an operation such as an operation of turning the apparatus 2 on or off.

The apparatus 2 to be operated by the non-contact operating switch 1 is, for example, a lighting device (not illustrated in FIG. 3) mounted on a washing stand. In this case, for example, when a user brings his or her hand close to the sensor 10 in order to operate the lighting device as illustrated in FIG. 3, the sensor 10 generates a detection signal indicating that the user's hand has been detected. The control unit 20 receives the detection signal generated by the sensor 10, generates an operation signal for turning the lighting device on or off on the basis of this detection signal, and then supplies the operation signal to the lighting device. This allows a user to perform an operation such as an operation of turning the lighting device on or off.

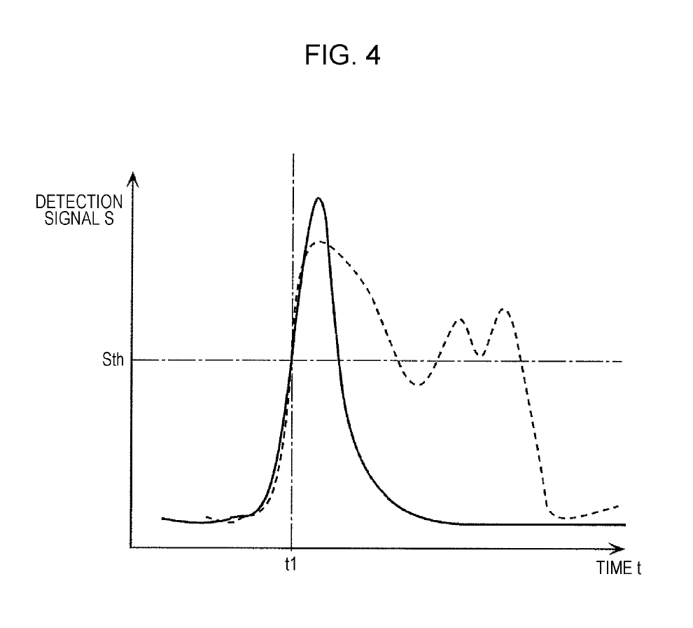

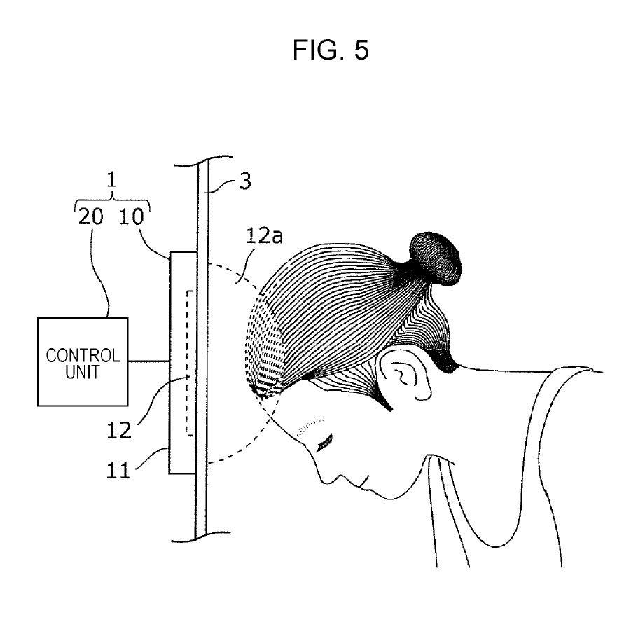

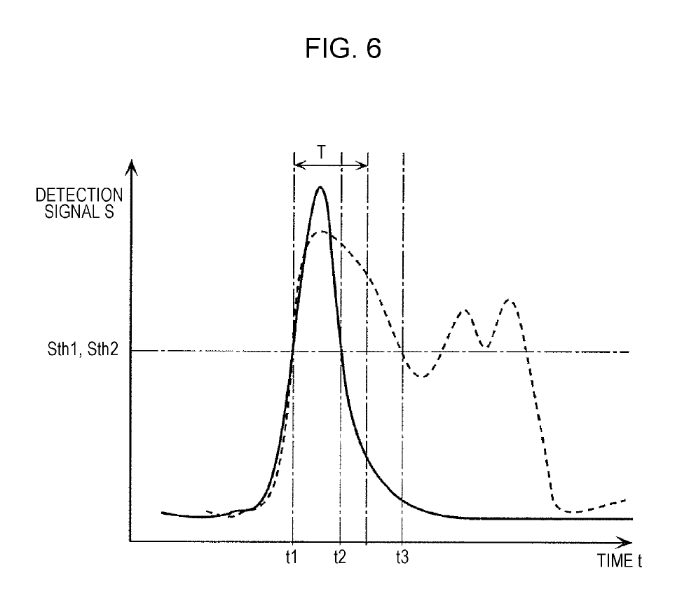

A method for controlling the non-contact operating switch 1 by the control unit 20 in the present embodiment is described below with reference to FIGS. 3, 4, and 6. FIG. 4 is a diagram for explaining a method for controlling a non-contact operating switch according to a comparative example. FIG. 5 is a diagram illustrating a state where a user's head is close to a non-contact operating switch. FIG. 6 is a diagram for explaining a method for controlling the non-contact operating switch 1 according to Embodiment 1.

As illustrated in FIG. 4, when a detection signal S generated by the sensor 10 exceeds a threshold value Sth (at a time t1 in FIG. 4), it is determined that a target to be detected has been detected, and an operation signal for operating an apparatus to be operated is generated and supplied to the apparatus.

This allows a user to operate the apparatus to be operated (e.g., a lighting device) at the time t1 by bringing his or her hand to the sensor 10 in order to operate the apparatus to be operated as illustrated in FIG. 3. For example, the lighting device can be turned on or off at the time t1 as illustrated in FIG. 4.

However, according to the method for controlling a non-contact operating switch illustrated in FIG. 4, there are cases where the non-contact operating switch reacts even when a user does not intend to operate an apparatus. That is, there are cases where the non-contact operating switch reacts to an operation that is not intended by the user.

For example, in a case where a user's head comes close to the sensor 10 unintentionally and exists in the detection region 12a during face washing as illustrated in FIG. 5, the non-contact operating switch reacts when a detection signal S generated by the sensor 10 exceeds the threshold value Sth. As a result, the apparatus to be operated is operated although the user does not intend to operate the apparatus. Specifically, the lighting device is turned on or off at the time t1 although the user does not intend to turn the lighting device on or off.

Also in a case where a user's arm comes close to the sensor 10 unintentionally and exists in the detection region 12a during shaving, brushing of teeth, or the like, the non-contact operating switch reacts.

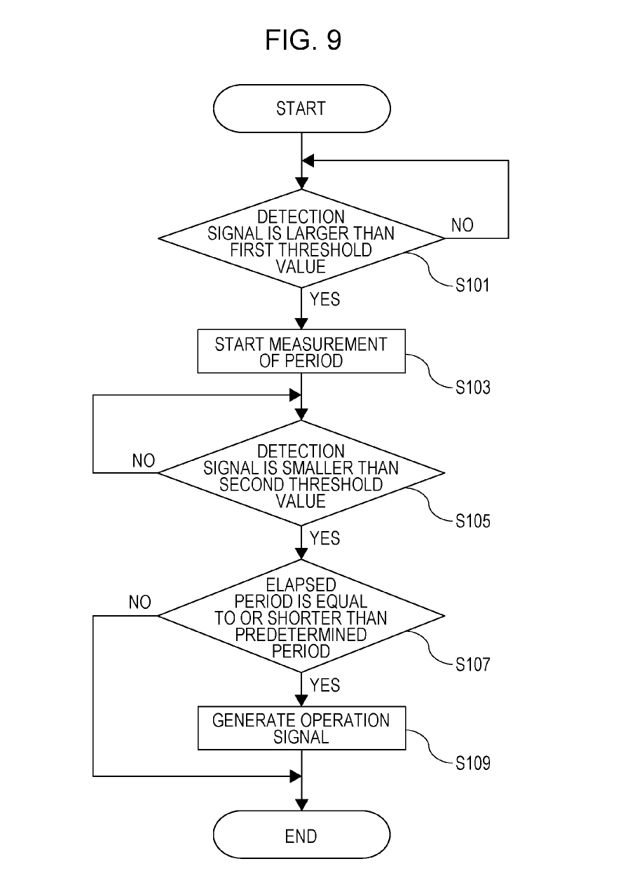

In view of this, the non-contact operating switch 1 according to the present embodiment is configured to react to an operation that is intended by a user but is configured not to react to an operation that is not intended by a user by the following detection determining algorithm. FIG. 9 is a flowchart illustrating an example of processing of the control unit 20 of the non-contact operating switch 1 according to the present embodiment.

Specifically, the control unit 20 compares a detection signal S generated by the sensor 10 and a first threshold value Sth1 as illustrated in FIGS. 6 and 9 (S101). In a case where the detection signal S exceeds the first threshold value Sth1 (YES in S101), the control unit 20 starts measurement of a period (S103). Next, the control unit 20 compares the detection signal S and a second threshold value Sth2 (S105). In a case where the detection signal S becomes smaller than the second threshold value Sth2 (YES in S105), the control unit 20 compares an elapsed period and a predetermined period T (S107). In a case where the elapsed period is equal to or shorter than the predetermined period T as indicated by the solid line in FIG. 6 (YES in S107), the control unit 20 generates an operation signal (S109). Meanwhile, in a case where the detection signal S becomes smaller than the second threshold value Sth2 after elapse of the predetermined period T from the time when the detection signal S exceeds the first threshold value Sth1 (YES in S101) as indicated by the dotted line in FIG. 6, the control unit 20 does not generate an operation signal. That is, in a case of NO in S107, no operation signal is generated. In the present embodiment, the first threshold value Sth1 and the second threshold value Sth2 are the same.

According to this processing, in a case where a user brings his or her hand close to the non-contact operating switch 1 and promptly withdraws the hand in order to operate an apparatus to be operated such as a lighting device as illustrated in FIG. 3, the user's hand is brought close to the sensor 10 at the time t1 and is withdrawn away from the sensor 10 at a time t2, for example, in FIG. 6. In this case, a period in which the user's hand is close to the sensor 10 is short. Accordingly, the detection signal S becomes smaller than the second threshold value Sth2 at the time t2, which is within the predetermined period T from the time t1 at which the detection signal S exceeds the first threshold value Sth1 as illustrated in FIG. 6. In this case, the control unit 20 generates an operation signal for operating the apparatus to be operated and supplies the operation signal to the apparatus. As a result, the apparatus is operated at the time t2. In this way, the user can operate the apparatus to be operated as intended by the user. For example, the user can turn the lighting device on or off.

Meanwhile, in a case where a user washes his or her face as illustrated in FIG. 5, the user's head is close to the sensor 10 for a long period (e.g., several seconds). Accordingly, the detection signal S becomes smaller than the second threshold value Sth2 at a time t3, i.e., after elapse of the predetermined period T from the time t1 at which the detection signal S exceeds the first threshold value Sth1, as illustrated in FIG. 6. In this case, the control unit 20 does not generate an operation signal for operating the apparatus to be operated. Accordingly, the apparatus to be operated is not operated. That is, the lighting device is not turned on or off when the user washes his or her face.

According to the control method according to the present embodiment illustrated in FIG. 6, a period from the time when a user operates the non-contact operating switch 1 to the time when an apparatus is actually operated is longer by a degree corresponding to a delay period from the time t1 to the time t2 than the control method illustrated in FIG. 4. However, the delay period from the time t1 to the time t2 is extremely short (e.g., approximately 0.1 seconds to 0.3 seconds). Therefore, the user can control the apparatus without being conscious of the delay period.

The predetermined period T is a certain length of period from the time t1 at which the detection signal S generated by the sensor 10 reaches the first threshold value Sth1. The predetermined period T can be set to any length. For example, in a case where the predetermined period T is equal to or shorter than 1 second, the non-contact operating switch 1 can have good reactivity.

As described above, according to the non-contact operating switch 1 according to the present embodiment, an operation signal is generated in a case where the detection signal S becomes smaller than the second threshold value Sth2 within the predetermined period T from the time when the detection signal S exceeds the first threshold value Sth1, whereas no operation signal is generated in a case where the detection signal S becomes smaller than the second threshold value Sth2 after elapse of the predetermined period T from the time when the detection signal S exceeds the first threshold value Sth1.

With this arrangement, the non-contact operating switch 1 reacts to an operation intended by a user but does not react to an operation that is not intended by a user. It is therefore possible to prevent the non-contact operating switch 1 from mistakenly reacting to an operation that is not intended by a user. As a result, for example, the non-contact operating switch 1 can be configured to react only to an operation using a user's hand intended by the user, and it is therefore possible to prevent erroneous operation caused by an operation that is not intended by the user such as an operation using a user's head, arm, or the like.

### Embodiment 2

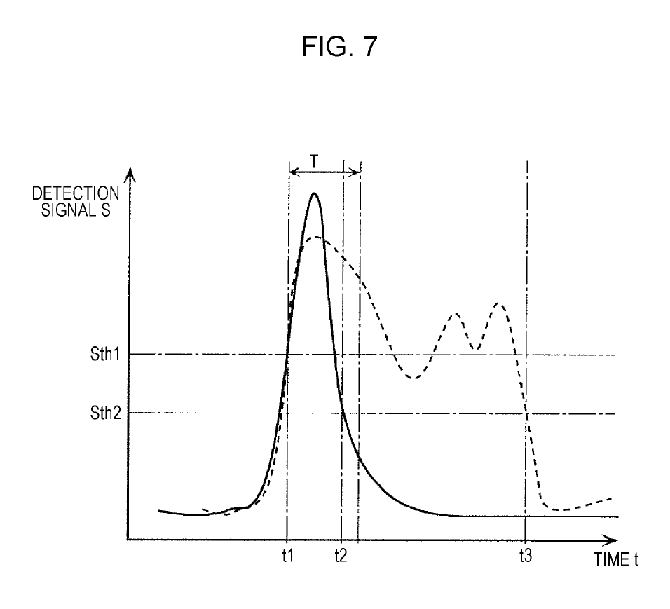

Next, a non-contact operating switch according to Embodiment 2 is described with reference to FIG. 7. FIG. 7 is a diagram for explaining a method for controlling the non-contact operating switch according to Embodiment 2.

As illustrated in FIG. 7, also in the non-contact operating switch according to the present embodiment, a control unit 20 generates an operation signal in a case where a detection signal S generated by a sensor 10 becomes smaller than a second threshold value Sth2 within a predetermined period T from a time when the detection signal S exceeds a first threshold value Sth1, whereas the control unit 20 generates no operation signal in a case where the detection signal S generated by the sensor 10 becomes smaller than the second threshold value Sth2 after elapse of the predetermined period T from the time when the detection signal S exceeds the first threshold value Sth1, as in Embodiment 1.

A difference between the non-contact operating switch according to the present embodiment and the non-contact operating switch 1 according to Embodiment 1 lies in threshold values of the detection signal S. Specifically, in the non-contact operating switch 1 according to Embodiment 1, the first threshold value Sth1 and the second threshold value Sth2 are the same. Meanwhile, in the non-contact operating switch according to the present embodiment, the first threshold value Sth1 and the second threshold value Sth2 are different as illustrated in FIG. 7. More specifically, in the present embodiment, the first threshold value Sth1 is larger than the second threshold value Sth2.

In this case, in a case where a user brings his or her hand close to the non-contact operating switch 1 and promptly withdraws the hand in order to operate an apparatus to be operated as illustrated in FIG. 3, the detection signal S exceeds the first threshold value Sth1 at a time t1 and then becomes smaller than the second threshold value Sth2 at a time t2, which is within the predetermined period T from the time t1, as illustrated in FIG. 7. In this case, the control unit 20 generates an operation signal for operating the apparatus to be operated and supplies the operation signal to the apparatus, and as a result, the user can operate the apparatus to be operated as intended by the user.

Meanwhile, in a case where a user washes his or her face as illustrated in FIG. 5, the detection signal S exceeds the first threshold value Sth1 at the time t1 and then becomes smaller than the second threshold value Sth2 at a time t3, i.e., after elapse of the predetermined period T. In this case, the control unit 20 does not generate an operation signal for operating the apparatus to be operated, and as a result, the apparatus to be operated is not operated.

As described above, according to the non-contact operating switch according to the present embodiment, an operation signal is generated in a case where the detection signal S becomes smaller than the second threshold value Sth2 within the predetermined period T from the time when the detection signal S exceeds the first threshold value Sth1, whereas no operation signal is generated in a case where the detection signal S becomes smaller than the second threshold value Sth2 after elapse of the predetermined period T from the time when the detection signal S exceeds the first threshold value Sth1, as in Embodiment 1.

This makes it possible to prevent the non-contact operating switch 1 from reacting to an operation that is not intended by a user, as in Embodiment 1. For example, it is possible to prevent erroneous reaction of the non-contact operating switch 1 caused by an operation resulting from a user's head or arm that is not intended by a user.

Furthermore, in the present embodiment, the first threshold value Sth1 is larger than the second threshold value Sth2.

This makes a period from the time t1 to the time t2 longer than that in Embodiment 1. As a result, it is possible to determine with more certainty whether the detection signal S generated by the sensor 10 is one that is intended by a user or one that is not intended by a user. It is therefore possible to prevent the non-contact operating switch 1 from reacting to an operation that is not intended by a user with more certainty. For example, it is possible to prevent erroneous reaction of the non-contact operating switch 1 caused by an operation resulting from a user's head or arm that is not intended by a user with more certainty.

### Embodiment 3

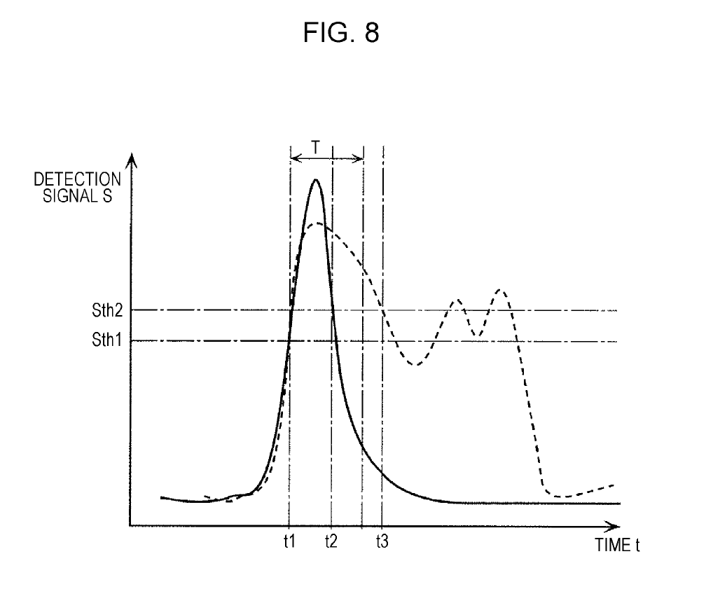

Next, a non-contact operating switch according to Embodiment 3 is described with reference to FIG. 8. FIG. 8 is a diagram for explaining a method for controlling the non-contact operating switch according to Embodiment 3.

As illustrated in FIG. 8, also in the non-contact operating switch according to the present embodiment, a control unit 20 generates an operation signal in a case where a detection signal S generated by a sensor 10 becomes smaller than a second threshold value Sth2 within a predetermined period T from a time when the detection signal S exceeds a first threshold value Sth1, whereas the control unit 20 generates no operation signal in a case where the detection signal S generated by the sensor 10 becomes smaller than the second threshold value Sth2 after elapse of the predetermined period T from the time when the detection signal S exceeds the first threshold value Sth1, as in Embodiment 1.

A difference between the non-contact operating switch according to the present embodiment and the non-contact operating switch 1 according to Embodiment 1 lies in threshold values of the detection signal S. Specifically, in the non-contact operating switch 1 according to Embodiment 1, the first threshold value Sth1 and the second threshold value Sth2 are the same. Meanwhile, in the non-contact operating switch according to the present embodiment, the first threshold value Sth1 and the second threshold value Sth2 are different, as in Embodiment 2. More specifically, in the present embodiment, the first threshold value Sth1 is larger than the second threshold value Sth2. However, unlike Embodiment 2, in the present embodiment, the first threshold value Sth1 is smaller than the second threshold value Sth2 as illustrated in FIG. 8.

In this case, in a case where a user brings his or her hand close to the non-contact operating switch 1 and promptly withdraws the hand in order to operate an apparatus to be operated as illustrated in FIG. 3, the detection signal S exceeds the first threshold value Sth1 at a time t1 and then becomes smaller than the second threshold value Sth2 at a time t2, which is within the predetermined period T from the time t1, as illustrated in FIG. 8. In this case, the control unit 20 generates an operation signal for operating the apparatus to be operated and supplies the operation signal to the apparatus, and as a result, the user can operate the apparatus to be operated as intended by the user.

Meanwhile, in a case where a user washes his or her face as illustrated in FIG. 5, the detection signal S exceeds the first threshold value Sth1 at the time t1 and then becomes smaller than the second threshold value Sth2 at a time t3, i.e., after elapse of the predetermined period T. In this case, the control unit 20 does not generate an operation signal for operating the apparatus to be operated, and as a result, the apparatus to be operated is not operated.

As described above, according to the non-contact operating switch according to the present embodiment, an operation signal is generated in a case where the detection signal S becomes smaller than the second threshold value Sth2 within the predetermined period T from the time when the detection signal S exceeds the first threshold value Sth1, whereas no operation signal is generated in a case where the detection signal S becomes smaller than the second threshold value Sth2 after elapse of the predetermined period T from the time when the detection signal S exceeds the first threshold value Sth1, as in Embodiments 1and 2.

This makes it possible to prevent the non-contact operating switch 1 from reacting to an operation that is not intended by a user, as in Embodiments 1 and 2. For example, it is possible to prevent erroneous reaction of the non-contact operating switch 1 caused by an operation resulting from a user's head or arm that is not intended by a user.

Furthermore, in the present embodiment, the first threshold value Sth1 is smaller than the second threshold value Sth2.

This makes a period from the time t1 to the time t2 shorter than that in Embodiment 1. As a result, it is possible to improve reactivity of the non-contact operating switch. It is therefore possible to provide a non-contact operating switch that makes it possible to prevent erroneous operation caused by an operation resulting from a user's head or arm that is not intended by a user and that is good in reactivity.

### Modification etc.

A non-contact operating switch according to the present disclosure has been described above on the basis of Embodiments 1 through 3. However, the present disclosure is not limited to Embodiments 1 through 3.

For example, the sensor 10 is a capacitance-type sensor in Embodiments 1 through 3 but is not limited to this. The sensor 10 may be, for example, an infrared sensor or the like that includes a light receiving unit for receiving an infrared ray reflected or radiated by a target to be detected and detects approach of a target to be detected by detecting an infrared ray reflected or radiated by the target to be detected.

In addition, various modifications of the embodiments above which a person skilled in the art can conceive of and any combinations of constituent elements and functions in Embodiments 1 through 3 are also encompassed within the present disclosure as long as such modifications and combinations are not deviated from the purpose of the present disclosure.

What is claimed is:

1. A switch for operating an apparatus, the switch comprising:
a sensor that, in operation, outputs a detection signal indicative of approach of a target without making contact with the target; and
a control circuit that, in operation, generates an operation signal for operating the apparatus based on the detection signal supplied from the sensor, wherein:
the control circuit generates the operation signal when the detection signal becomes smaller than a second threshold value within a predetermined period from a time when the detection signal exceeds a first threshold value that is different from the second threshold value, and
the control circuit does not generate the operation signal when the detection signal becomes smaller than the second threshold value after elapse of the predetermined period from the time when the detection signal exceeds the first threshold value.

2. The switch according to claim 1, wherein
the first threshold value is larger than the second threshold value.

3. The switch according to claim 1, wherein
the first threshold value is smaller than the second threshold value.

4. The switch according to claim 1, wherein
the sensor includes an electrode that, in operation, detects a change of electrostatic capacitance that occurs between the target and the sensor.

5. The switch according to claim 1, wherein
the sensor includes a light receiver that, in operation, receives an infrared ray reflected or radiated by the target and outputs the detection signal upon receiving the infrared ray.
